(19) United States
(12) Patent Application Publication
(10) Pub. No.: US 2014/0197326 A1
(43) Pub. Date: Jul. 17, 2014

(54) CHARGED PARTICLE BEAM WRITING METHOD

(71) Applicant: NUFLARE TECHNOLOGY, INC., Kanagawa (JP)

(72) Inventor: Takayuki OHNISHI, Shizuoka (JP)

(73) Assignee: NUFLARE TECHNOLOGY, INC., Kanagawa (JP)

(21) Appl. No.: 14/149,478

(22) Filed: Jan. 7, 2014

(30) Foreign Application Priority Data
Jan. 16, 2013 (JP) 2013-005138

(51) Int. Cl. H01J 37/147; H01J 37/317

(52) U.S. Cl. CPC H01J 37/147; H01J 37/3174
USPC 250/396 R

(57) ABSTRACT

A charged particle beam writing method comprising, an irradiation step of irradiating a sample with a charged particle beam emitted from a charged particle source, a first blanking step of performing the blanking while the charged particle beam is moved in a first direction from a position of the charged particle beam in the irradiation step; and a second blanking step of performing the blanking the charged particle beam is moved in a second direction opposite to the first direction from the position of the charged particle beam in the irradiation step.

### CROSS-REFERENCE TO THE RELATED APPLICATION

The entire disclosure of the Japanese Patent Application No. 2013-005138, filed on Jan. 16, 2013 including specification, claims, drawings, and summary, on which the Convention priority of the present application is based, are incorporated herein in its entirety.

### FIELD OF THE INVENTION

The present invention relates to a charged particle beam writing method.

### BACKGROUND

Recently, a circuit dimension required for a semiconductor element becomes finer and finer with high integration and large capacity of a Large Scale Integration (LSI).

Using an original image pattern (referring to a mask or a reticle, hereinafter collectively referred to as a mask) in which a circuit pattern is formed, a circuit is formed by exposing and transferring a pattern onto a wafer with a reduced-projection exposure apparatus that is called a stepper or a scanner, thereby reproducing the semiconductor element. At this point, in a production of the mask used to transfer the fine circuit pattern to the wafer, a charged particle beam writing apparatus such as electron beam writing apparatus is used, and a writing method in which an electron beam is used as a charged particle beam is performed (for example, see Japanese Unexamined Patent Application Publication No. Hei05-144711, and Japanese Unexamined Utility Model Application Publication No. Sho53-13070).

FIG. 9 is a schematic view illustrating a configuration of a conventional electron beam writing apparatus. Referring to FIG. 9, an electron beam writing apparatus 1001 includes a writing chamber 1011, a stage 1021 that is provided in the writing chamber 1011 to place a mask 1022 thereon, and an electro-optical lens barrel 1031 that is disposed in a ceiling portion of the writing chamber 1011. An electron gun 1032, a blanking deflector 1041, a blanking aperture 1042, deflectors 1033 and 1035, and a shaping aperture 1034 are provided in the electro-optical lens barrel 1031. During a writing period, a mask 1022 on a lower side is irradiated with an electron beam B emitted from the electron gun 1032 on an upper side. At this point, a shape and a size of the electron beam B are adjusted by the deflectors 1033 and 1035 and the shaping aperture 1034, and an irradiation position on the mask 1022 is also determined by the deflectors 1033 and 1035 and the shaping aperture 1034.

During a non-writing period, blanking is performed using a blanking deflector 1041 and a blanking aperture 1042. That is, the electron beam B is deflected by the blanking deflector 1041, and the electron beam B is blocked by the blanking aperture 1042 such that the mask 1022 is not irradiated therewith. The details are as follows.

During the non-writing period, the blanking deflector 1041 is put into an on state to establish an on state of the blanking, and the electron beam B is deflected by the blanking deflector 1041. The blanking aperture 1042 is irradiated with the electron beam B. As a result, the electron beam B is blocked by the blanking aperture 1042, but the mask 1022 on the lower side is not irradiated with the electron beam B. During the writing period, the blanking deflector 1041 is put into an off state to establish an off state of the blanking, and the electron beam B is not deflected by the blanking deflector 1041 such that the mask 1022 on the lower side is irradiated with the electron beam B as described above.

In FIG. 9, the stage 1021 on which the mask 1022 is placed is attached to a bottom portion of the writing chamber 1011. The stage 1021 is configured to be movable by a driving unit 1025 in an X-direction and a Y-direction, which are orthogonal to each other. A laser interferometer 1023 is fixed to a sidewall of the writing chamber 1011. A position of a mirror 1024 provided in the neighborhood of an end portion of the stage 1021 is measured with the laser interferometer 1023 to recognize a position of the stage 1021.

As described above, in the conventional electron beam writing method in which the electron beam writing apparatus 1001 is used, the on/off control of the electron beam B is performed by the control of the blanking such that the mask 1022 is irradiated or not irradiated with the electron beam B.

In the conventional electron beam writing method, whether the electron beam B is deflected is determined by selecting the on state or the off state of the blanking deflector 1041, thereby performing the on/off control of the electron beam B. Accordingly, in the conventional electron beam writing method, the deflection of the electron beam B is controlled and the electron beam B is moved according to the on/off control of the electron beam B performed by the blanking. That is, the electron beam B is swung and moved onto the blanking aperture 1042 from a shot position on the mask 1022 in the writing period.

At this point, a current distribution is generated in a shot of the electron beam B on the mask 1022 by the movement of the electron beam B. For example, the distribution in which an energy amount increases gradually in the moving direction of the electron beam B in the on state of the blanking is generated in the shot of the electron beam B. In the shot of the electron beam B, an irradiation time of the electron beam B is relatively lengthened along the moving direction of the electron beam B in the on state of the blanking, which results in the distribution in which the energy amount increases gradually in the moving direction of the electron beam B.

The generation of the distribution becomes pronounced with increasing current density of the electron beam B used, and becomes too large to ignore as a current error in the shot. The desired shape of the shot is not maintained when the current error becomes too large to be accepted in the shot. As a result, CD (Critical Dimension of Pattern size) accuracy is degraded in the conventional electron beam writing method in which the electron beam writing apparatus 1001 is used. Additionally, position accuracy is degraded because an energy distribution of the electron beam B becomes asymmetric.

The present invention has been devised to solve the problem described above. An object of the present invention is to provide a charged particle beam writing method in which the degradation of the CD accuracy and the position accuracy is suppressed.

Other challenges and advantages of the present invention are apparent from the following description.

### SUMMARY OF THE INVENTION

According to one aspect of the present invention, a charged particle beam writing method comprising, an irradiation step of irradiating a sample with a charged particle beam emitted from a charged particle source, a first blanking step of performing the blanking while the charged particle beam is moved in a first direction from a position of the charged particle beam in the irradiation step, and a second blanking step of performing the blanking the charged particle beam is moved in a second direction opposite to the first direction from the position of the charged particle beam in the irradiation step.

Further to this aspect of the present invention, the charged particle beam writing method, wherein the first blanking step and the second blanking step are alternately provided with the irradiation step interposed therebetween.

Further to this aspect of the present invention, the charged particle beam writing method, wherein a moving speed of the charged particle beam in the first blanking step is substantially equal to a moving speed of the charged particle beam in the second blanking step.

Further to this aspect of the present invention, the charged particle beam writing method, wherein in the first blanking step the blanking is performed using a first blanking deflector and a blanking aperture located a distance ha away from the first blanking deflector, the second blanking step is performed using the second blanking deflector and the blanking aperture located a distance hb away from the second blanking deflector, wherein the first blanking deflector, second blanking deflector and blanking aperture, are sequentially provided from a side of the charged particle source between the charged particle source and the sample, and a blanking voltage applied to the second blanking deflector in the second blanking step is larger than a blanking voltage applied to the first blanking deflector in the first blanking step by a factor of (ha/hb).

Further to this aspect of the present invention, the charged particle beam writing method, wherein the charged particle beam is an electron beam, and the electron beam has a current density of 1000 A/cm² or more.

### BRIEF DESCRIPTION OF THE DRAWINGS

FIG. 1 illustrates a writing unit of an electron beam writing apparatus according to the first embodiment of the present invention.

FIG. 2 is a view schematically illustrating a first blanking deflector in the electron beam writing apparatus according to the first embodiment of the present invention.

FIG. 3 is a table in which estimation results of the current error are summarized in an electron beam writing method.

FIG. 4 is a view schematically illustrating a first blanking deflector and a second blanking deflector in the electron beam writing apparatus according to the first embodiment of the present invention.

FIG. 5 is a view schematically illustrating the action of the electron beam writing apparatus according to the first embodiment of the present invention.

FIG. 6 is a view illustrating the correction of the moving speed of the electron beam in the blanking of the electron beam writing method according to the first embodiment of the present invention.

FIG. 7 is a flowchart illustrating an electron beam writing method according to the second embodiment of the present invention.

FIG. 8 is a view schematically illustrating the blanking performed in synchronization with the shot of the electron beam to the sample in the electron beam writing method according to the second embodiment of the present invention.

FIG. 9 is a schematic view illustrating a configuration of a conventional electron beam writing apparatus.

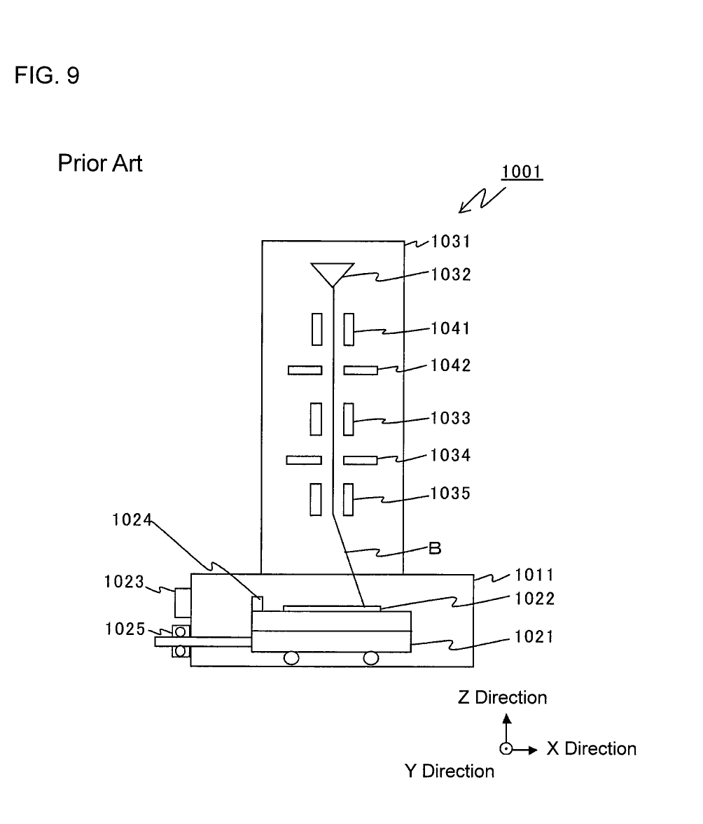

### DETAILED DESCRIPTION OF THE EMBODIMENTS

### First Embodiment

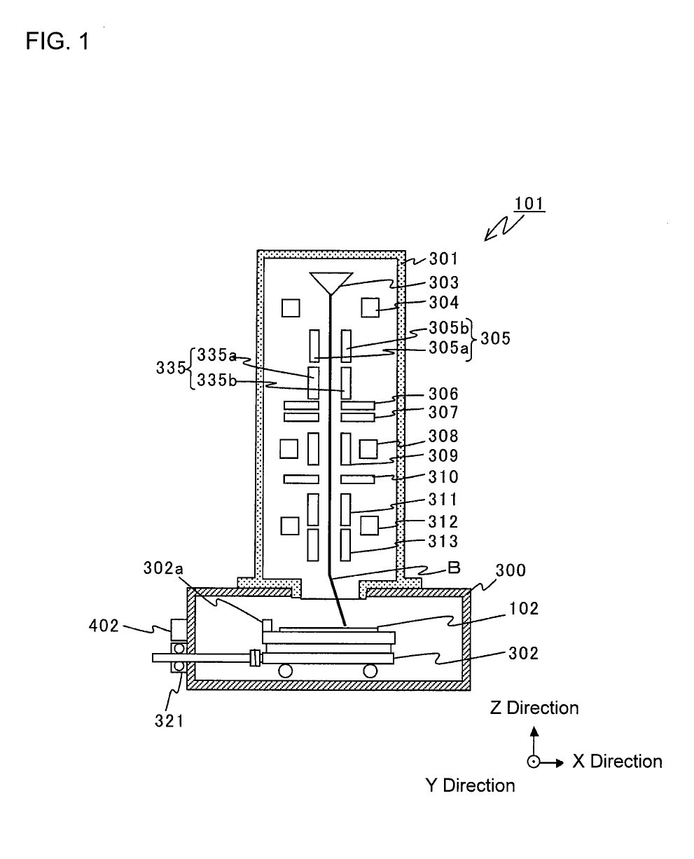

FIG. 1 is a view illustrating a configuration of a writing unit of an electron beam writing apparatus according to the first embodiment of the present invention.

An electron beam writing apparatus 101 according to a first embodiment of the present invention is a variable shaping type electron beam writing apparatus. FIG. 1 illustrates a writing unit of the electron beam writing apparatus 101. The writing unit generates an electron beam B, and irradiates a sample 102 with the electron beam B. A controller (not illustrated) is connected to the writing unit. The controller controls a shape and an irradiation position of the electron beam B in the writing unit, irradiation timing, blanking timing, and a position of the sample 102.

The writing unit includes a writing chamber 300 and an electro-optical lens barrel (also referred to as a column) 301 provided in a ceiling portion of the writing chamber 300. A part of the writing chamber 300 is opened on the ceiling portion side, and a space of the electro-optical lens barrel 301 and a space of the writing chamber 300 connected with each other. A stage 302 described below is disposed in the writing chamber 300. Accordingly, in the writing unit, the stage 302 in the writing chamber 300 is irradiated with the electron beam B through the electro-optical lens barrel 301.

An electron beam emitting unit is provided in the electro-optical lens barrel 301 in order to emit the electron beam B toward the stage 302. In FIG. 1, an electron gun 303 that emits the electron beam B, a lighting lens 304, a first blanking deflector 305, a second blanking deflector 335, a blanking aperture 306, a first shaping aperture 307, a projection lens 308, a shaping deflector 309, a second shaping aperture 310, a sub-deflector 311, an objective lens 312, and a main deflector 313 are disposed in order from the top of the apparatus. These units constitute the electron beam emitting unit. In the electron beam emitting unit of the electro-optical lens barrel 301, the electron beam B is emitted from the electron gun 303 on an upper side, and the stage 302 on a lower side in the writing chamber 300 is irradiated with the electron beam B.

The electron beam writing apparatus 101 of the first embodiment includes the first blanking deflector 305 that is disposed on the lower side (sample side) of the lighting lens 304 and the second blanking deflector 335 that is disposed adjacent to the lower side of the first blanking deflector 305 as a blanking deflector used in blanking. That is, the electron beam writing apparatus 101 of the first embodiment includes a two-stage blanking deflector including the first blanking deflector 305 constituting a first stage and the second blanking deflector 335 constituting a second stage toward the lower side that is of the side of the stage 302 from the upper side that is of the side of the electron gun 303. In the electron beam writing apparatus 101 of the first embodiment, the blanking aperture 306 is disposed adjacent to the lower side of the second blanking deflector 335.

As illustrated in FIG. 1, the first blanking deflector 305 may be an electrostatic deflection type blanking deflector including a set of blanking electrodes 305a and 305b and a power supply (not illustrated) that is electrically connected to the blanking electrodes 305a and 305b. A blanking voltage BV is applied to the blanking electrodes 305a and 305b for the purpose of the blanking, and the first blanking deflector 305 becomes the on state, thereby deflecting the passing electron beam B. The electron beam writing apparatus 101 enables the blanking using the first blanking deflector 305 and the blanking aperture 306.

As illustrated in FIG. 1, the second blanking deflector 335 may be also the electrostatic deflection type blanking deflector including a set of blanking electrodes 335a and 335b and the power supply (not illustrated) that is electrically connected to the blanking electrodes 335a and 335b. Separately from the first blanking deflector 305, the blanking voltage BV is applied to the blanking electrodes 335a and 335b for the purpose of the blanking, and the second blanking deflector 335 becomes the on state, thereby deflecting the passing electron beam B. The electron beam writing apparatus 101 enables the blanking using the second blanking deflector 335 and the blanking aperture 306.

At this point, the voltage having a polarity opposite to that of the first blanking deflector 305 is applied to the second blanking deflector 335, because the blanking voltage BV is applied to the blanking electrodes 335a and 335b to put the second blanking deflector 335 into the on state. As a result, a deflection direction of the electron beam B of the blanking performed by the first blanking deflector 305 and the blanking aperture 306 and a deflection direction of the electron beam B of the blanking performed by the second blanking deflector 335 and the blanking aperture 306 are opposite to each other. It is assumed that a Z-direction is the irradiation direction of the electron beam B from the upper side to the lower side, and that a +X-direction perpendicular to the Z-direction is the deflection direction of the electron beam B of the blanking performed by the first blanking deflector 305 and the blanking aperture 306. In such cases, the deflection direction of the electron beam B of the blanking performed by the second blanking deflector 335 and the blanking aperture 306 becomes a −X-direction that is perpendicular to the Z-direction and opposite to the +X-direction.

As described above, the electron beam writing apparatus 101 includes the first blanking deflector 305 and the second blanking deflector 335, and the first blanking deflector 305 and the second blanking deflector 335 can separately be used to deflect the electron beam B. As a result, the first blanking deflector 305 and the second blanking deflector 335 can independently perform the blanking using the blanking aperture 306, and perform the on/off control of the electron beam B.

The first blanking deflector 305 and the second blanking deflector 335 can be put into the off state in which the blanking voltage BV is not applied. At this point, the electron beam B emitted from the electron gun 303 is not deflected, but the first shaping aperture 307 is irradiated with the electron beam B through the lighting lens 304. In the electron beam writing apparatus 101, the above control is performed during the writing period.

As described above, the on state of the blanking is established during the non-writing period. That is, the blanking voltage BV is applied to one of the first blanking deflector 305 and the second blanking deflector 335, and the blanking deflector to which the blanking voltage BV is applied is put into the on state. The electron beam B is deflected by the blanking deflector, which is put into the on state. As a result, not the first shaping aperture 307 but the blanking aperture 306 is irradiated with the deflected electron beam B.

A rectangular opening is provided in the first shaping aperture 307 of the electron beam writing apparatus 101. Therefore, a cross-section of the electron beam B with which the first shaping aperture 307 is irradiated during the writing period is formed into the rectangular shape when the electron beam B passes through the first shaping aperture 307. Then the electron beam B is projected onto the second shaping aperture 310 through the projection lens 308. At this point, the shaping deflector 309 changes the place where the second shaping aperture 310 is irradiated with the electron beam B, thereby controlling the shape and the size of the electron beam B.

The electron beam B passing through the second shaping aperture 310 is focused on the sample 102 through the objective lens 312. The sub-deflector 311 and the main deflector 313 control the irradiation position of the electron beam B on the sample 102.

The stage 302 is provided in the writing chamber 300. The sample 102 is supported by a pin (not illustrated) provided on the stage 302. For example, the sample 102 is a mask in which a light shielding film such as a chromium film and a resist film are stacked on a glass substrate.

The stage 302 is configured to be movable by a driving unit 321 in the X-direction and the Y-direction, which are orthogonal to each other. A laser interferometer 402 is fixed to a sidewall of the writing chamber 300. A mirror 302a is provided on the stage 302 at the position different from the sample 102. A laser beam from the laser interferometer 402 is reflected by the mirror 302a to measure and recognize the position of the stage 302.

In the electron beam writing apparatus 101 of the first embodiment of the present invention having the above configuration, the first blanking deflector 305 and the second blanking deflector 335 disposed so as to become two stages from the upper side toward the lower side along the irradiation direction of the electron beam B are used. The blanking of the electron beam B can be performed in synchronization with the shot with the electron beam B onto the sample 102, and the degradation of the CD accuracy (Critical Dimension) and the position accuracy can be suppressed. An electron beam writing method of the present invention will be described below. The electron beam writing apparatus 101 of the first embodiment is used in the electron beam writing method of the present invention.

### Second Embodiment

Preferably the electron beam writing apparatus 101 of the first embodiment described above is used in an electron beam writing method according to a second embodiment of the present invention. As described above, the electron beam writing apparatus 101 includes the first blanking deflector 305 and the second blanking deflector 335, which are disposed so as to become the two stages from the upper side toward the lower side along the irradiation direction of the electron beam B. In the electron beam writing apparatus 101, the first blanking deflector 305 and the second blanking deflector 335 are independently used in the blanking of the electron beam B. In the first blanking deflector 305 and the second blanking deflector 335, the blanking can independently be performed using the blanking aperture 306 to switch between the on and off states of the electron beam B. At this point, the deflection direction in the blanking performed by the first blanking deflector 305 and the blanking aperture 306 and the deflection direction in the blanking performed by the second blanking deflector 335 are opposite to each other.

In the electron beam writing method of the second embodiment, using the function of electron beam writing apparatus 101, the electron beam writing can be performed while the degradation of the CD accuracy and the position accuracy is suppressed.

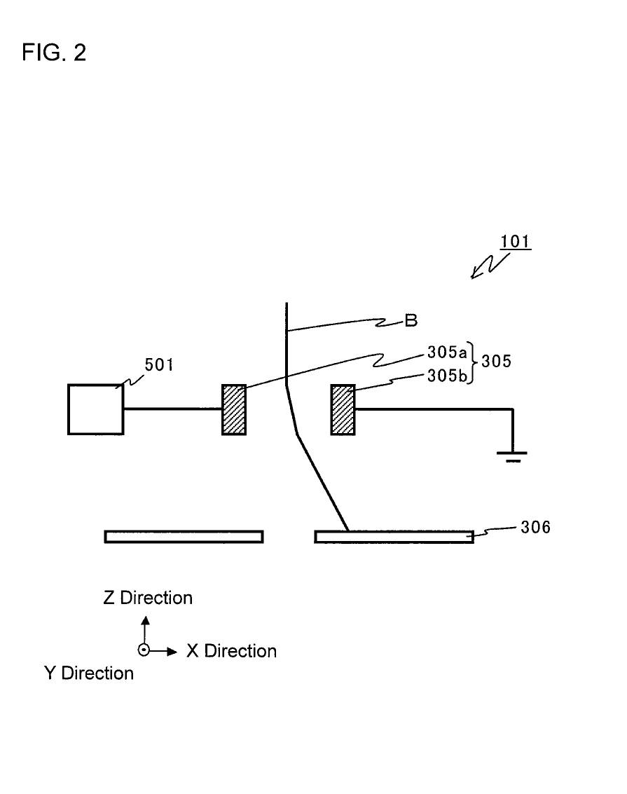

FIG. 2 is a view schematically illustrating the first blanking deflector in the electron beam writing apparatus of the first embodiment.

FIG. 2 schematically illustrates a power supply 501 included in the electron beam writing apparatus 101, and the power supply 501 is connected to a blanking electrode 305a of the first blanking deflector 305. FIG. 2 also illustrates the action of the first blanking deflector 305 to the electron beam B.

As illustrated in FIG. 2, in the first blanking deflector 305, for example, the blanking voltage BV of −5 V is applied to the blanking electrode 305a on the side of the power supply 501. The blanking voltage BV having any voltage may be applied as long as the electron beam B can sufficiently be deflected.

In the electron beam writing apparatus 101, the first blanking deflector 305 is put into the on state by applying the blanking voltage BV to the blanking electrode 305a. During the writing period in the on state of the blanking, the electron beam B is swung and moved onto the blanking aperture 306 from the position where the shot is performed onto the sample 102 (not illustrated in FIG. 2). That is, the electron beam B is deflected by the first blanking deflector 305, and moved in one direction, namely, the +X-direction in FIG. 2.

At this point, the electron beam B with which the sample 102 is irradiated is moved in one direction in response to the deflection of the electron beam B. As a result, a current distribution is generated in the shot of the electron beam B by the movement of the electron beam B. That is, the distribution in which an energy amount increases gradually toward the moving direction of the electron beam B is generated in the shot of the electron beam B. This is because, in the shot of the electron beam B, an irradiation time of the electron beam B is relatively lengthened along the moving direction of the electron beam B in the on state of the blanking.

The generation of the current distribution becomes pronounced with increasing current density of the electron beam B used, and detected as a current error in the shot. When the current error is generated and enlarged in the shot, the desired shape of the shot is not maintained. As a result, in the electron beam writing method in which only the first blanking deflector 305 is used in the blanking in the electron beam writing apparatus 101, there is a risk of degrading the CD accuracy and the position accuracy as in the conventional electron beam writing method.

In the electron beam writing method, the current error generated by the blanking in the shot can be estimated according to the following formula (1). That is, the current error (blanking error amount (%)) can be estimated using a time (T1) necessary for a blanking operation, a time (shot time) (T2) necessary for one-time shot of the electron beam B, an aperture diameter (S) of the first shaping aperture 307 of the electron beam writing apparatus 101 in FIG. 1, and a distance (swing width) (L) in which the electron beam B is swung and moved by the blanking.

Current Error=(T1/T2)×(S/L)×2 (Formula 1)

In the shot of the electron beam B, the current distribution is generated twice, namely, the time the electron beam B is moved in the on state of the blanking, and the time the blanking is put into the off state to return the electron beam B to a predetermined position for the purpose of the shot. Accordingly, the current error expressed by the formula (1) is defined by multiplication of a constant of 2.

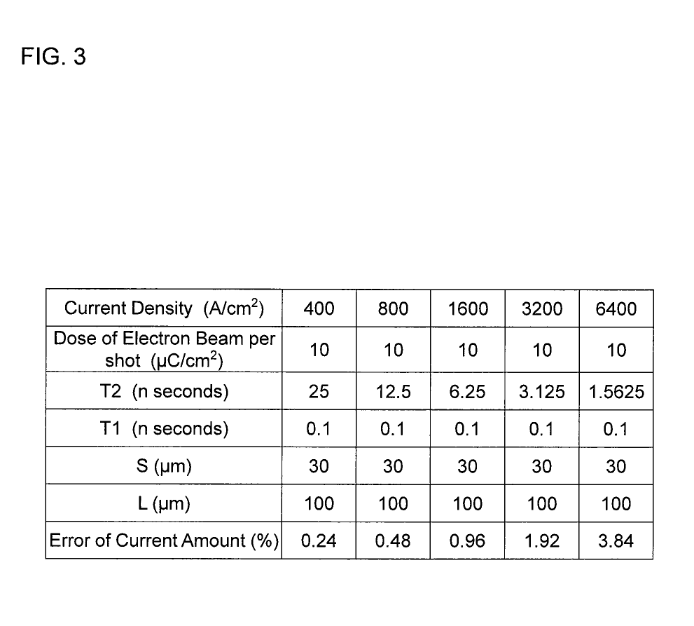

FIG. 3 is a table in which estimation results of the current error are summarized in the electron beam writing method.

In the table in FIG. 3, it is assumed that the shot of the electron beam B is performed on the condition that the current density varies, and that the blanking in FIG. 2 is performed in synchronization with the shot. The generated current error (%) is calculated using the formula (1) and summarized.

In the table in FIG. 3 using the formula (1), it is assumed that the electron beam per shot is an irradiation amount of 10 μC/cm², that the time (T1) necessary for the blanking operation is 0.1 n (nano) second, that the aperture diameter (S) is 30 μm, and the distance (swing width) (L) in which the electron beam is swung and moved by the blanking is 100 μm.

As is clear from the estimation result illustrated by the table in FIG. 3, when the blanking in FIG. 2 is performed, the current distribution is generated to increase the current error in the shot with increasing current density of the electron beam B. Particularly, it is considered that the current error exceeds 0.5% for the current density of 1000 A/cm² or more. The current error becomes pronounced in the shot when exceeding 0.5%. The current error becomes an unacceptable magnitude in the shot, the desired shape of the shot is hardly maintained, and the current error is detected as the degradation of the CD accuracy and the position accuracy. Accordingly, it is considered that the current error becomes a level at which a need for a measure is raised when the electron beam B has the current density of 1000 A/cm² or more.

As described above, in the electron beam writing method in which only the first blanking deflector 305 is used in the electron beam writing apparatus 101 of the first embodiment, the current distribution is generated in the shot by the blanking of the electron beam B synchronized with the shot of the electron beam B. With increasing current density of the electron beam B, the current distribution increases, and the current error increases in the shot.

As described above, the increase in current error is similar to that of the conventional electron beam writing apparatus 1001, and there is a risk of degrading the CD accuracy and the position accuracy in the electron beam writing. Therefore, in the electron beam writing method of the second embodiment, the electron beam writing apparatus 101 of the first embodiment is used, and the degradation of the CD accuracy and the position accuracy is suppressed using the function of the electron beam writing apparatus 101.

Specifically, the electron beam writing method of the second embodiment, the electron beam writing apparatus 101 of the first embodiment is used, and the second blanking deflector 335 is used in the blanking together with the first blanking deflector 305. In the electron beam writing, the blanking is performed by a combination of the first blanking deflector 305 and the second blanking deflector 335 to suppress the degradation of the CD accuracy and the position accuracy.

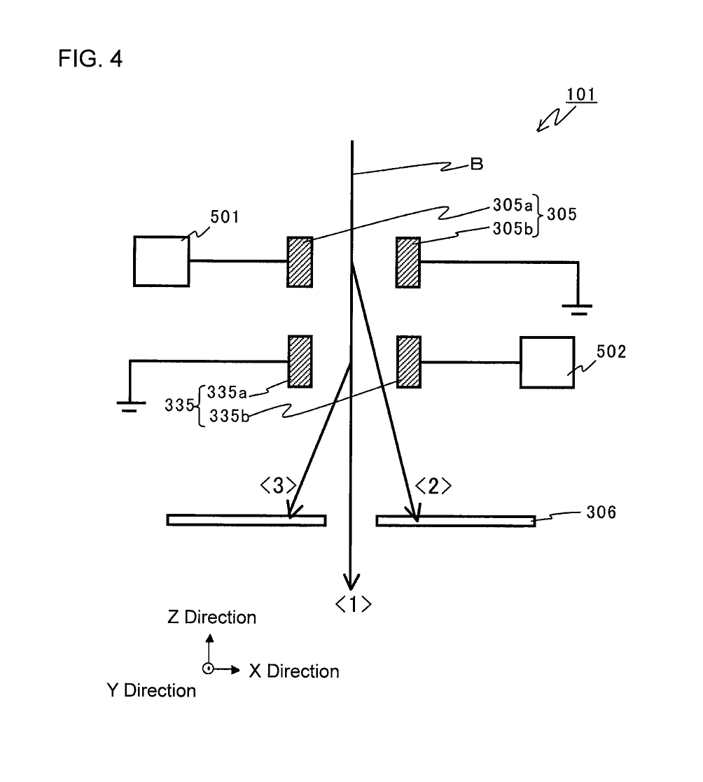

FIG. 4 is a view schematically illustrating the first blanking deflector and the second blanking deflector in the electron beam writing apparatus of the first embodiment.

FIG. 4 schematically illustrates the power supply 501 included in the electron beam writing apparatus 101, in which the power supply 501 is connected to the blanking electrode 305a of the first blanking deflector 305. FIG. 4 also illustrates a power supply 502 included in the electron beam writing apparatus 101, in which the power supply 502 is connected to the blanking electrode 335b of the second blanking deflector 335. FIG. 4 also illustrates the action of the first blanking deflector 305 and the second blanking deflector 335 to the electron beam B.

During the writing period, both the first blanking deflector 305 and the second blanking deflector 335 are put into the off state. As illustrated in FIG. 4, the electron beam B is not deflected, but passes through the blanking aperture 306 and is located in a position <1> where the shot is irradiated on the sample 102 (not illustrated in FIG. 4).

During the non-writing period, one of the first blanking deflector 305 and the second blanking deflector 335 is put into the on state.

In the case that the first blanking deflector 305 is put into the on state while the second blanking deflector 335 is put into the off state, the blanking voltage BV is applied to the blanking electrode 305a on the side of the power supply 501 in the first blanking deflector 305 as illustrated in FIG. 4. The blanking voltage BV may have any voltage as long as the electron beam B can sufficiently be deflected.

During the writing period in the on state of the blanking, the electron beam B is swung in the +X-direction as shown in FIG. 4 from the position <1> where the shot is performed on the sample 102 and moved to a position <2> on the blanking aperture 306. Therefore, the electron beam B is blocked by the blanking aperture 306.

In the case that the second blanking deflector 335 is put into the on state while the first blanking deflector 305 is put into the off state, the blanking voltage BV is applied to the blanking electrode 335b on the side of the power supply 502 in the second blanking deflector 335 as illustrated in FIG. 4. The blanking voltage BV may have any voltage as long as the electron beam B can sufficiently be deflected.

During the writing period in the on state of the blanking, the electron beam B is swung in the −X-direction as shown in FIG. 4 from the position <1> where the shot is performed on the sample 102 and moved to a position <3> on the blanking aperture 306. Therefore, the electron beam B is blocked by the blanking aperture 306.

At this point, in the case that the first blanking deflector 305 is put into the on state, the electron beam B with which the sample is irradiated moves in one direction on the sample 102 according to the deflection of the electron beam B. As a result, as described above, the current distribution is generated in the shot of the electron beam B. That is, the distribution in which the energy amount increases gradually toward the moving direction of the electron beam B is generated in the shot of the electron beam B.

On the other hand, even if the second blanking deflector 335 is put into the on state, the electron beam B with which the sample is irradiated moves in one direction opposite to that in the on state of the first blanking deflector 305 on the sample 102 according to the deflection of the electron beam B. As a result, although the current distribution is generated in the shot of the electron beam B, the current distribution in the on state of the first blanking deflector 305 is characteristically opposite to this. That is, although the distribution in which the energy amount increases gradually toward the moving direction of the electron beam B is generated in the shot of the electron beam B, the distribution has the characteristic opposite to that in the on state of the first blanking deflector 305.

Accordingly, in performing the blanking of the electron beam B in synchronization with the shot of the electron beam B to the sample 102, when the blanking performed by the first blanking deflector 305 and the blanking performed by the second blanking deflector 335 are combined in one shot, the current distributions, which are generated by the blanking performed by the first blanking deflector 305 and the blanking performed by the second blanking deflector 335, cancel each other out in the shot of the electron beam B.

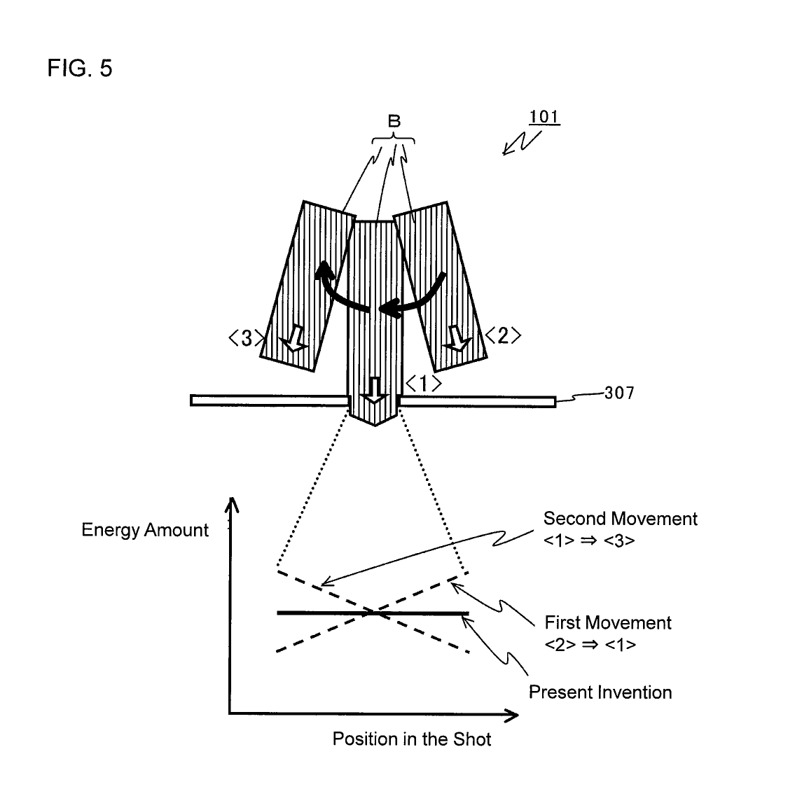

FIG. 5 is a view schematically illustrating the action of the electron beam writing apparatus of the first embodiment.

FIG. 5 is a view schematically illustrating the distribution of the amount of energy, which is generated by the blanking in the electron beam writing apparatus 101, in the shot of the electron beam B. In the graph in FIG. 5, an x-axis (horizontal axis) indicates the position in the shot of the electron beam B, and a y-axis (vertical axis) indicates the energy amount. A broken line indicates the distribution of the amount of energy, which is generated by each movement of the electron beam B performed by the blanking, in the shot of the electron beam B.

As illustrated in FIG. 5, for example, in the case that the first blanking deflector 305 performs the blanking to the electron beam B to locate the electron beam B in the position <2> on the blanking aperture 306 (not illustrated in FIG. 5), the electron beam B moves to the position <1> in the off state of the blanking. For the sake of convenience, the movement will be referred to as a first movement. The cross-section of the electron beam B with which the first shaping aperture 307 is irradiated through the blanking aperture 306 is formed into the rectangular shape when the electron beam B passes through the first shaping aperture 307. At this point, the distribution of the energy amount indicated by the broken line as the “first movement” in FIG. 5 is generated in the shot of the electron beam B having the rectangular cross-section.

In the case that the blanking is performed with the electron beam B located in the position <1> after the shot is performed with the desired irradiation amount, the electron beam B is deflected using the second blanking deflector 335, and moved to the position <3> on the blanking aperture 306. For the sake of convenience, the movement will be referred to as a second movement. At this point, the distribution of the energy amount indicated by the broken line as a “second movement” in FIG. 5 is generated in the shot of the electron beam B having the rectangular cross-section.

In the electron beam writing apparatus 101, in the case that the electron beam writing is performed in association with the blanking, the direction of the first movement and the direction of the second movement are opposite to each other. Accordingly, in the shot of the electron beam B, the energy distributions of the first movement and the second movement exert the characteristics opposite to each other with respect to the position in the shot as illustrated in FIG. 5. The energy distributions of the first movement and the second movement overlap each other and cancel each other in the shot of the electron beam B. That is, the shot of the electron beam B having the flat energy amount distribution without gradient is obtained as indicated by the solid line as “the present invention” in FIG. 5.

As a result, the generation of the current distribution in the shot due to the blanking of the electron beam B synchronized with the shot of the electron beam B can be suppressed in the electron beam writing method of the second embodiment in which the first blanking deflector 305 and the second blanking deflector 335 are used in the electron beam writing apparatus 101 of the first embodiment. Even if the current density of the electron beam B increases, the increase in current error can be prevented in the shot to suppress the degradation of the CD accuracy and the position accuracy.

At this point, preferably the first movement and the second movement are performed at an identical speed in order to suppress the generation of the current distribution in the shot of the electron beam B with higher accuracy. Therefore, the current distributions generated by the first movement and the second movement in the shot of the electron beam B cancel each other out with higher accuracy.

The speeds of the first movement and the second movement can be controlled by the blanking voltages BV applied to the blanking electrode 305a of the first blanking deflector 305 and the blanking electrode 335b of the second blanking deflector 335. That is, in the first blanking deflector 305 and the second blanking deflector 335, the speeds of the first movement and the second movement can be controlled by adjusting the blanking voltages BV.

In the electron beam writing apparatus 101 in FIG. 4, the first blanking deflector 305 and the second blanking deflector 335 are provided along the irradiation direction of the electron beam B, a distance between the first blanking deflector 305 and the blanking aperture 306 differs from a distance between the second blanking deflector 335 and the blanking aperture 306. The distance between the second blanking deflector 335 and the blanking aperture 306 is shorter than the distance between the first blanking deflector 305 and the blanking aperture 306.

Therefore, even if the blanking voltages BV having an identical absolute value are applied to the first blanking deflector 305 and the second blanking deflector 335, the speeds of the first movement and the second movement are not matched to each other. Accordingly, it is necessary to correct the blanking voltage BV at the first blanking deflector 305 and the second blanking deflector 335. For example, it is necessary to correct the blanking voltage BV at the second blanking deflector with respect to the blanking voltages BV at the first blanking deflector.

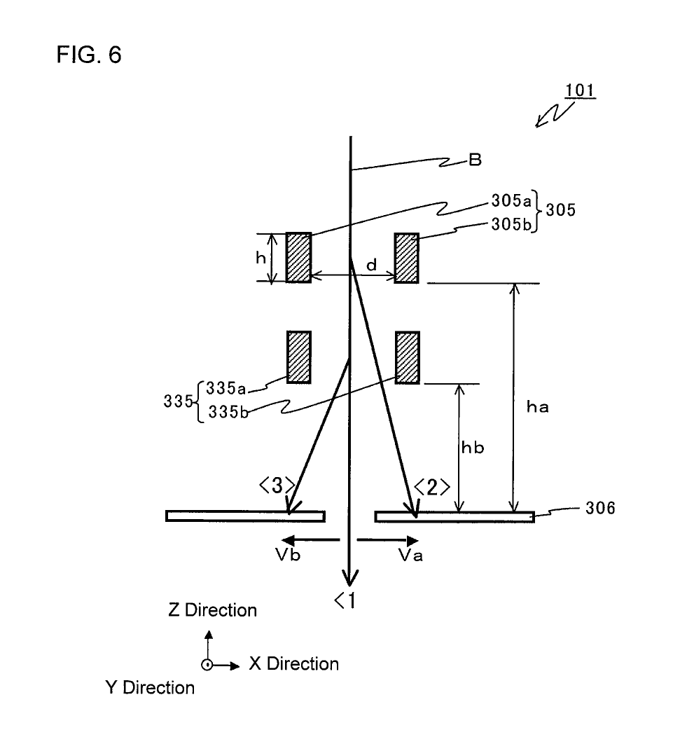

FIG. 6 is a view illustrating the correction of the moving speed of the electron beam in the blanking of the electron beam writing method of the second embodiment.

FIG. 6 schematically illustrates the first blanking deflector 305, the second blanking deflector 335, and the blanking aperture 306 in the electron beam writing apparatus 101 of the first embodiment.

A ratio (Va/Vb) of a speed (Va) of the first movement and a speed (Vb) of the second movement in the blanking is expressed by Vb/Va=hb/ha using a distance ha between the first blanking deflector 305 and the blanking aperture 306 and a distance hb between the second blanking deflector 335 and the blanking aperture 306.

Accordingly, the speed (Vb) of the second movement in the blanking can be expressed by Vb=(hb/ha)×Va. As can be seen from this formula, a difference in speed between the first movement and the second movement in the deflection increases with increasing difference between the distance ha between the first blanking deflector 305 and the blanking aperture 306 and the distance hb between the second blanking deflector 335 and the blanking aperture 306. As a result, the characteristics of the current distributions generated by the first movement and the second movement in the shot of the electron beam B have different tendencies (different gradients), and the current distributions generated by the first movement and the second movement becomes difficult to cancel each other out.

Therefore, the speed (Vb) of the second movement can be matched to the speed (Va) of the first movement by multiplying (Vb) by (ha/hb).

For example, for the first blanking deflector 305 in FIG. 6, a relationship between a moving speed V of the electron beam B in the blanking on the blanking aperture 306 and the applied blanking voltage BV can be expressed by the following formula (2). Where e is a charge of an electron, h is a height of the blanking electrodes 305a and 305b in the Z-direction, m is a mass of the electron, d is an inter-electrode distance, and Vz is a speed of the electron of the electron beam B in the Z-direction.

V=(e×BV×h)/(m×d×Vz) (Formula 2)

A proportional relationship holds for the relationship between the moving speed V of the electron beam B in the blanking on the blanking aperture 306 and the applied blanking voltage BV.

In the case that the blanking voltage BV at the second blanking deflector 335 is corrected with respect to the blanking voltage BV at the first blanking deflector 305, the correction can be performed by multiplying the blanking voltage BV at the second blanking deflector 335 by (ha/hb).

Similarly the blanking voltages BV at the first blanking deflector 305 and the second blanking deflector 335 can be corrected by multiplying the blanking voltage BV at the first blanking deflector 305 by (hb/ha).

The electron beam writing method of the second embodiment will more specifically be described with reference to the drawings.

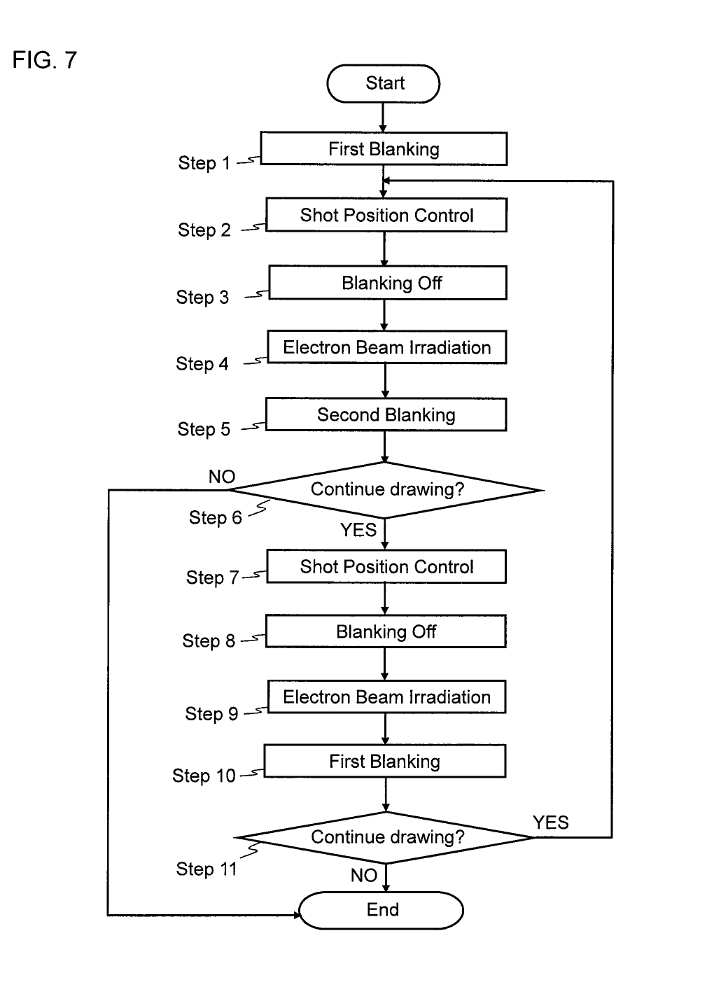

FIG. 7 is a flowchart illustrating the electron beam writing method of the second embodiment.

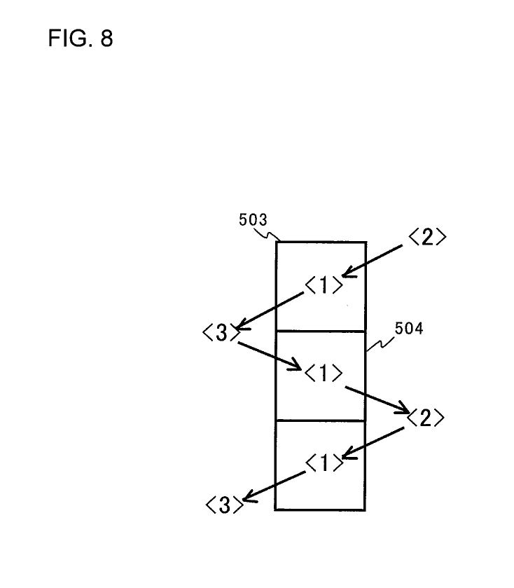

FIG. 8 is a view schematically illustrating the blanking performed in synchronization with the shot of the electron beam to the sample in the electron beam writing method of the second embodiment.

In FIG. 7, it is assumed that first blanking is the blanking, in which the blanking voltage BV is applied to the first blanking deflector 305 to deflect the electron beam B located in the position <1> and the electron beam B is moved to the position <2> in FIGS. 4 and 6, and it is assumed that second blanking is the blanking, in which the blanking voltage BV is applied to the second blanking deflector 335 to deflect the electron beam B located in the position <1> and the electron beam B is moved to the position <3> in FIGS. 4 and 6. The description of the electron beam writing method of the second embodiment with reference to FIGS. 7 and 8 is made by referring to FIGS. 1, 4, and 6 used in the electron beam writing apparatus 101 of the first embodiment.

As illustrated in FIG. 7, in the electron beam writing method of the second embodiment, the first blanking is performed (Step 1). In the first blanking, the blanking voltage BV is applied to the first blanking deflector 305 to deflect the electron beam B located in the position <1>, and the electron beam B is moved to the position <2> in FIGS. 4 and 6. For example, the blanking voltage BV can be set to +5 V. However, the blanking voltage BV may have any voltage as long as the blanking can be correctly performed. As illustrated in FIG. 8, the electron beam B is located in the position <2> through Step 1.

The position of a shot 503 of the electron beam B is controlled (Step 2). For example, the sub-deflector 311 controls the position of the shot 503. Sometimes the main deflector 313 or the stage 302 controls the position of the shot 503. As illustrated in FIG. 8, when the electron beam B is located in the position <1>, the shot of the electron beam B is irradiated in the desired position on the sample 102 through Step 2.

The application of the blanking voltage BV to the first blanking deflector 305 is stopped to put the first blanking deflector 305 into the state in which the voltage is not applied, and the blanking is put into the off state (Step 3). As illustrated in FIG. 8, through Step 3, the deflection of the electron beam B is stopped to return the electron beam B to the position <1> from the position <2>. The shot of the electron beam B is irradiated in the desired position on the sample 102.

Then the sample 102 is irradiated with the electron beam B located in the position <1> until a desired irradiation amount is satisfied (Step 4).

The second blanking is performed (Step 5). In the second blanking, the blanking voltage BV is applied to the second blanking deflector 335 to deflect the electron beam B located in the position <1>, and the electron beam B is moved to the position <3> in FIGS. 4 and 6. As described above, the blanking voltage BV applied in the second blanking is larger than the blanking voltage BV applied in the first blanking by a factor of (ha/hb).

The movement to return the electron beam B in Step 3, and the movement in the second blanking generate the current distributions in the shot 503 of the electron beam B on the sample 102. However, in the current distributions, the energy amounts increase gradually in the directions opposite to each other and characteristics thereof are opposite. Accordingly, the current distribution generated in the shot 503 of the electron beam B by the movement of the electron beam B in Step 3 is canceled by the movement in the second blanking. The current distributions cancel out each other with higher accuracy by performing the above described correction to the blanking voltage BV in the second blanking.

As illustrated in FIG. 8, the electron beam B is located in the position <3> in Step 5.

Whether the writing (shot) is further performed is determined in Step 6. When the writing is further performed, the flow goes to Step 7. When the writing is not further performed, the electron beam writing method of the second embodiment is finished.

The position of the shot 504 of the electron beam B is controlled (Step 7). For example, the sub-deflector 311 controls the position of the shot 504. As illustrated in FIG. 8, when the electron beam B is located in the position <1>, the shot of the electron beam B is irradiated in the desired position on the sample 102 through Step 7.

The application of the blanking voltage BV to the second blanking deflector 335 is stopped to put the second blanking deflector 335 into the state in which the voltage is not applied, and the blanking is put into the off state (Step 8). As illustrated in FIG. 8, through Step 8, the deflection of the electron beam B is eliminated to return the electron beam B to the position <1> from the position <3>. The shot of the electron beam B is irradiated in the desired position on the sample 102.

Then the sample 102 is irradiated with the electron beam B located in the position <1> until the desired irradiation amount is satisfied (Step 9).

Similarly as in Step 1, the first blanking is performed (Step 10). In the first blanking, the blanking voltage BV is applied to the first blanking deflector 305 to deflect the electron beam B located in the position <1>, and the electron beam B is moved to the position <2> in FIGS. 4 and 6. As illustrated in FIG. 8, the electron beam B is located in the position <2> in Step 10.

Similarly to Step 6, whether the writing (shot) is further performed is determined in Step 11. When the writing is further performed, the flow returns to Step 2, and Steps 2 to 10 described above are repeated. When the writing is not further performed, the electron beam writing method of the second embodiment is ended.

As described above, the first blanking deflector 305 and the second blanking deflector 335 of the electron beam writing apparatus 101 of the first embodiment in FIG. 1 are used in the electron beam writing method of the second embodiment. The first blanking deflector 305 and the second blanking deflector 335 deflect the electron beam B in the directions opposite to each other. As illustrated in FIG. 8, the blanking of the electron beam B synchronized with the shots 503 and 504 of the electron beam B can suppress the generation of the current distributions in the shots 503 and 504. As a result, even if the current density of the electron beam B increases, the increase in current error is prevented in the shots 503 and 504, and the degradation of the CD accuracy and the position accuracy can be suppressed. The features and advantages of the present invention are summarized as follows.

The present invention can provide the charged particle beam writing method in which the degradation of the CD accuracy and the position accuracy is suppressed.

The present invention is not limited to the above embodiments and may be modified in various forms without departing from the scope of the invention. Further, in the above-mentioned execution of the present invention an electron beam was used, however, the present invention is not limited thereto and may utilize a different charged particle beam, for example an ion beam.

What is claimed is:

1. A charged particle beam writing method comprising:
an irradiation step of irradiating a sample with a charged particle beam emitted from a charged particle source;
a first blanking step of performing the blanking while the charged particle beam is moved in a first direction from a position of the charged particle beam in the irradiation step; and
a second blanking step of performing the blanking the charged particle beam is moved in a second direction opposite to the first direction from the position of the charged particle beam in the irradiation step.

2. The charged particle beam writing method according to claim 1, wherein the first blanking step and the second blanking step are alternately provided with the irradiation step interposed therebetween.

3. The charged particle beam writing method according to claim 1, wherein a moving speed of the charged particle beam in the first blanking step is substantially equal to a moving speed of the charged particle beam in the second blanking step.

4. The charged particle beam writing method according to claim 1, wherein in the first blanking step the blanking is performed using a first blanking deflector and a blanking aperture located a distance ha away from the first blanking deflector;
the second blanking step is performed using the second blanking deflector and the blanking aperture located a distance hb away from the second blanking deflector,
wherein the first blanking deflector, second blanking deflector and blanking aperture, are sequentially provided from a side of the charged particle source between the charged particle source and the sample; and
a blanking voltage applied to the second blanking deflector in the second blanking step is larger than a blanking voltage applied to the first blanking deflector in the first blanking step by a factor of (ha/hb).

5. The charged particle beam writing method according to claim 1, wherein the charged particle beam is an electron beam, and the electron beam has a current density of 1000 A/cm² or more.
